(19) United States
(12) Patent Application Publication
(10) Pub. No.: US 2011/0174368 A1
(43) Pub. Date: Jul. 21, 2011

(54) COMPOSITE ELECTROLYTE AND THE PREPARATION METHOD THEREOF, AND DYE-SENSITIZED SOLAR CELL USING THE SAME

(76) Inventors: Sang-Soo LEE, Seoul (KR); Jong-Hyuk PARK, Seoul (KR); Jun-Kyung KIM, Seoul (KR)

(21) Appl. No.: 12/323,500

(22) Filed: Nov. 26, 2008

(30) Foreign Application Priority Data
Dec. 10, 2007 (KR) 10-2007-0127809

(51) Int. Cl. H01L 31/0224; H01L 51/44; H01L 31/02

(52) U.S. Cl. 136/256; 252/62.2

(57) ABSTRACT

A composite electrolyte, a preparation method thereof, and a dye-sensitized solar cell based on an electrolyte with hollow particles of metal oxide are disclosed. A dye-sensitized solar cell includes a photoelectrode substrate, a counter electrode substrate facing the photoelectrode substrate, a light absorbing layer formed on an inner surface of the photoelectrode substrate and having a dye adsorbed thereto, and a composite electrolyte, characterized in that an electrolyte is mixed with hollow particles composed of metal oxide particulates, filled between the light absorbing layer and the counter electrode substrate.

### CROSS-REFERENCE TO RELATED APPLICATION(S)

This application claims the benefit under 35 U.S.C. §119(a) of a Korean Patent Application No. 10-2007-0127809, filed on Dec. 10, 2007 in the Korean Intellectual Property Office, the entire disclosure of which is hereby incorporated by reference.

### TECHNICAL FIELD

The following description relates to a composite electrolyte, a preparation method thereof, and a dye-sensitized solar cell using the same, and more particularly, to a composite electrolyte which is capable of improving the mechanical strength of a solar cell, enhancing a diffusion coefficient of ions in an electrolyte and/or increasing a scattering effect of light, its preparation method, and a dye-sensitized solar cell using the same.

### BACKGROUND

Generally, a conventional silicon solar cell is constructed to have only one part for absorbing sunlight, generating and transferring electron-hole pairs, while a dye-sensitized solar cell is structured to have dye molecules for absorbing sunlight and generating electron-hole pairs, and a metal oxide semiconductor electrode for transferring the generated electrons.

As an example among currently known dye-sensitized solar cells, Gratzel et al. introduced a dye-sensitized solar cell in 1991 (U.S. Pat. No. 4,927,721; U.S. Pat. No. 5,350,644). Such dye-sensitized solar cell may have an inexpensive manufacturing cost per Watt when compared to a conventional silicon solar cell. Accordingly, it has drawn much attention due to its possibility of replacing the conventional solar cell.

FIG. 1 is a diagram illustrating the operational principle of a general dye-sensitized solar cell. Dye 12 adsorbed by a metal oxide semiconductor electrode 11 absorbs sunlight and performs an electron transition from a ground state (D⁺/D) to an excited state (D⁺/D*) so as to form an electron-hole pair. The electron in the excited state is injected into a conduction band (E_{CB}) of the metal oxide. The electron injected into the metal oxide semiconductor electrode 11 is transferred to a transparent conductive substrate 13 through an interface between particles, and is then moved to a counter electrode 15 coated with a platinum layer 16 through an external electric wire 14. An electrolyte with an oxidation-reduction (i.e., redox) pair 17 is injected between the metal oxide semiconductor electrode 11 and the counter electrode 15. The dye 12 having been oxidized by absorbing sunlight is reduced again by receiving an electron provided by the oxidation-reduction pair 17. Here, the oxidation-reduction pair 17 which provided the electron is reduced again by an electron reaching the counter electrode 15, thereby completing the operational cycle of the dye-sensitized solar cell. In addition, a load L is series-connected between the transparent conductive substrate 13 and the counter electrode 15 so as to enable the measurement of a short-circuit current, an open-circuit voltage, a fill factor, and the like. The solar cell performance, i.e., energy conversion efficiency, is determined by the short-circuit current, the open-circuit voltage and the fill factor of the solar cell. Accordingly, in order to enhance the solar cell performance, the value of each of these factors may be increased.

As representative methods for increasing such values in a dye-sensitized solar cell, there are a method for enhancing ion diffusion and a method for increasing the scattering effect of light. In particular, a dye-sensitized solar cell to which an electrolyte in the form of a gel, a pseudo-solid state and a solid state is adopted, may greatly contribute to enhancement of solar cell efficiency in that the energy conversion efficiency may be highly enhanced through enhancement of the ion diffusion, and where a light scattering effect is increased, light efficiency that dye may absorb may be maximized.

Accordingly, various methods for enhancing the ion diffusion or increasing the light scattering effect have been proposed.

However, such proposed methods regarding the dye-sensitized solar cell have only discussed separate applications with respect to such effects and the effects thereof. For such solar cells obtained by a combination of various kinds of components and physical properties, if all the individual material elements are included so as to accommodate a variety of reported enhancements, the expected enhancement in solar energy conversion efficiency may not be obtained due to destructive interference between conflicting physical properties.

Accordingly, there is a need for a material which is capable of enhancing one or more of the factors of ion diffusion, mechanical properties of the electrolyte, and the scattering effect of light, so as to improve the performance of a dye-sensitized solar cell.

### SUMMARY

Accordingly, according to one general aspect, there is provided a material capable of increasing the ion diffusion, mechanical properties as well as the light scattering effect of an electrolyte, and an electrolyte of a dye-sensitized solar cell using the same.

According to another aspect, there is provided a composite electrolyte, characterized in that an electrolyte is mixed with hollow particles composed of metal oxide particulates.

The weight percent of the hollow particles to the electrolyte may be 1:1000-2:1.

The hollow particles may have an average external diameter of 50 nm-100 μm, and the metal oxide particulates may have an average diameter of 1 nm-10 μm.

The hollow particles may have an average shell thickness of 10 nm-10 μm.

The metal oxide particulates may be one or a composite of two or more selected from a group consisting of Al oxide, Si oxide, Ti oxide, In oxide, Zn oxide, Sn oxide, W oxide, Pb oxide, Mg oxide, Ga oxide, Zr oxide, Sr oxide, Mo oxide, V oxide, Yr oxide, Sc oxide, Sm oxide, FeTi oxide, MnTi oxide, BaTi oxide and SrTi oxide.

According to yet another aspect, there is provided a dye-sensitized solar cell, including a photoelectrode substrate, a counter electrode substrate facing the photoelectrode substrate, a light absorbing layer formed on an inner surface of the photoelectrode substrate and having a dye adsorbed thereto, and a composite electrolyte, characterized in that an electrolyte is mixed with hollow particles composed of metal oxide particulates, filled between the light absorbing layer and the counter electrode substrate.

According to still another aspect, there is provided a preparation method for a composite electrolyte, the method including forming metal oxide adsorbents by adsorbing metal oxide particulates onto cores, and then obtaining hollow particles by removing the cores from the metal oxide adsorbents, and obtaining the composite electrolyte by mixing the hollow particles with an electrolyte.

The cores may be a polymer or its derivatives, or silica or its derivatives.

The polymer may be one or a composite of two or more selected from a group consisting of polystyrene, styrene/divinylbenzene copolymer, polymethylmethacrylate, polyvinyltoluene, and styrene/butadiene copolymer.

The cores may have an average diameter of 50 nm-100 μm.

The metal oxide particulates may be one or a composite of two or more selected from a group consisting of Al oxide, Si oxide, Ti oxide, In oxide, Zn oxide, Sn oxide, W oxide, Pb oxide, Mg oxide, Ga oxide, Zr oxide, Sr oxide, Mo oxide, V oxide, Yr oxide, Sc oxide, Sm oxide, FeTi oxide, MnTi oxide, BaTi oxide and SrTi oxide.

The diameter ratio of the cores to the metal oxide particulates may be in the range of 10:1-100000:1.

The metal oxide adsorbents may be formed by a dry method or a wet method, wherein the dry method is one of a mechanical adsorption using a mixing device, sputtering, e-beam evaporation, thermal evaporation, laser molecular beam epitaxy, pulsed laser deposition, MOCVD (Metal-Organic Chemical Vapor Deposition), HVPE (Hydiride Vapor Phase Epitaxy), electro deposition, atomic layer deposition, or MOMBE (Metal-Organic Molecular Beam Epitaxy), and wherein the wet method is one of emulsion polymerization, electrophoresis, dip coating, or a chemical vapor deposition using a surface functional group.

The removal of the cores from the metal oxide adsorbents may be performed by a heat treatment or a solution treatment, wherein the heat treatment comprises heating the metal oxide adsorbents at a rate of less than 10° C. per minute, and performing a heat treatment at a temperature in the range of 300-1000° C. for 5 min-48 hours, and wherein the solution treatment uses, as a solvent, one or a composite of two or more selected from a group consisting of water, alcohol, acetone, chloroform, methylene chloride, ethyl acetate, benzene, toluene, xylene, tetrahydrofuran, hexane, diethyl ether and hydrofluoric acid.

Other features will become apparent to those skilled in the art from the following detailed description, which, taken in conjunction with the attached drawings, discloses exemplary embodiments of the invention.

### BRIEF DESCRIPTION OF THE DRAWINGS

FIG. 1 is a schematic diagram illustrating an operational principle of a general dye-sensitized solar cell.

FIG. 2 is a diagram schematically illustrating a preparation method of hollow particles of metal oxides according to an exemplary embodiment.

FIG. 3 is a diagram schematically illustrating the promotion of ion diffusion and the increase of a light scattering effect where hollow particles of metal oxides according to an exemplary embodiment are applied.

FIG. 4 is a diagram schematically illustrating a structure of a dye-sensitized solar cell based on an electrolyte having hollow particles of metal oxides according to an exemplary embodiment.

FIG. 5A is an SEM (Scanning Electron Microscope) image of a polystyrene core before performing processing thereon.

FIG. 5B is an SEM image of hollow particles of metal oxides having their cores removed after Al₂O₃ nano particles are adsorbed into the cores through mechanofusion according to an exemplary embodiment.

FIG. 6 is diagram illustrating an UV permeability graph measuring the scattering effect of light in hollow particles of metal oxides according to an exemplary embodiment.

FIG. 7 is an image illustrating the gelation state of an electrolyte having hollow particles of metal oxides according to an exemplary embodiment.

FIG. 8 is a diagram illustrating a steady-state current graph measuring the degree of promoting the ion diffusion of an electrolyte to which hollow particles of metal oxides according to an exemplary embodiment are applied.

FIG. 9 is a diagram illustrating a current-voltage graph of a dye-sensitized solar cell prepared according to an exemplary embodiment obtained under the condition of AM 1.5, 100 mW/cm².

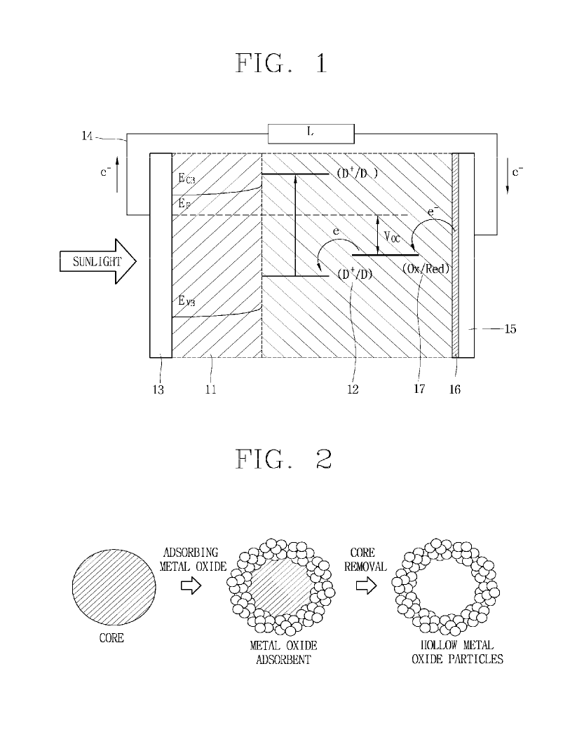

Throughout the drawings and the detailed description, unless otherwise described, the same drawing reference numerals will be understood to refer to the same elements, features, and structures. The elements may be exaggerated for clarity and convenience.

### DETAILED DESCRIPTION

The following detailed description is provided to assist the reader in gaining a comprehensive understanding of the methods, apparatuses and/or systems described herein. Accordingly, various changes, modifications, and equivalents of the systems, apparatuses and/or methods described herein will be suggested to those of ordinary skill in the art. Also, descriptions of well-known functions and constructions are omitted to increase clarity and conciseness.

A composite electrolyte, in which an electrolyte is mixed with hollow particles composed of metal oxide particulates may be referred to as “hollow particles of metal oxide,” “hollow particles,” or “hollow metal oxide particles.”

Referring to FIG. 2, a preparation method of a composite electrolyte according to an exemplary embodiment includes forming metal oxide adsorbents by adsorbing metal oxide particulates onto each surface of cores, obtaining hollow particles by removing each core from the metal oxide adsorbents, and adding the thusly obtained hollow particles into an electrolyte.

The core may be one or a composite of two or more selected from a group consisting of a polymer such as polystyrene, styrene/divinylbenzene copolymer, polymethylmethacrylate, polyvinyltoluene, styrene/butadiene copolymer and its derivatives, and SiO₂ and derivatives thereof. However, this is only exemplary and core materials are not limited thereto. As an additional example, core materials may includes any material capable of enhancing ion diffusion, mechanical properties of the electrolyte as well as the scattering effect of light, by adsorbing the metal oxides onto the surfaces of organic or inorganic particles representing various polymers.

The cores may have an average diameter of 50 nm-100 μm. Where the average diameter of the core is less than 50 nm, the scattering effect of light may be reduced. Where it is greater than 100 μm, viscosity may become too great, thereby making it difficult to process and reducing the scattering effect of light.

The metal oxide particulates may be one or a composite of two or more selected from a group consisting of Al oxide, Si oxide, Ti oxide, In oxide, Zn oxide, Sn oxide, W oxide, Pb oxide, Mg oxide, Ga oxide, Zr oxide, Sr oxide, Mo oxide, V oxide, Yr oxide, Sc oxide, Sm oxide, FeTi oxide, MnTi oxide, BaTi oxide and SrTi oxide, and more preferably, Al oxide, Si oxide and Ti oxide which can strongly interact with ions and have a large surface area. Again, this is only exemplary and metal oxide particulates are not limited thereto.

The metal oxide particulates may have an average diameter of 1 nm-10 μm, and more particularly, 0.001-0.1 μm. Where the average diameter of the metal oxide particulates is less than 1 nm, their preparation may be difficult and the adsorption process may not be performed well. Where it is greater than 10 μm, it may be difficult to fabricate hollow particles.

The metal oxide particulates to be adsorbed (i.e., an average shell thickness of the hollow particles to be prepared through following processes) may have an average thickness of 0.01-10 μm. Where the average thickness of the metal oxide particulates to be adsorbed is less than 0.01 μm, it may be difficult to maintain their hollow shape, and where it is greater than 10 μm, their advantageous physical properties as hollow particles may be lost.

The diameter ratio of the cores to the metal oxide particulates may be in the range of 10:1-100000:1. Ranges of less than 10:1 and greater than 100000:1 may make it difficult to prepare the hollow particles.

Methods for adsorbing the metal oxide particulates onto the core may be categorized into a dry method and a wet method.

Among the dry methods, there is a conventional mixing method using a mixer. In particular, there is a mechanical adsorption method by using more evolved mixing devices, such as mechanofusion, hybridizer, magnetically assisted impact coating, theta composer, and rotating fluidized bed coater (RFBC). In addition, a physical vapor deposition including sputtering, E-beam evaporation, thermal evaporation, laser molecular beam epitaxy, pulsed laser deposition, etc., a chemical vapor deposition including MOCVD (Metal-Organic Chemical Vapor Deposition), an HVPE (Hydiride Vapor Phase Epitaxy), etc., or a deposition including electro deposition, atomic layer deposition, MOMBE (Metal-Organic Molecular Beam Epitaxy), and the like may be employed.

In the wet method, emulsion polymerization, electrophoresis, dip coating, a chemical vapor deposition using surface functional group, etc. may be used.

A heat treatment and solution treatment may be used as a method for removing the cores so as to prepare the metal oxide particulates into a hollow shape after being coated onto each core.

A heat treatment may be used where a polymer substance is used as the core. The treatment may include heating at a rate of less than 10° C. per minute, and then performing a heat treatment at a temperature in the range of 300-1000° C. for 5 min.-48 hours. To maintain the hollow shape, it may be preferable to slowly heat at a rate of less than 1° C. per minute, and then perform a heat treatment at a temperature of more than 400° C. for more than 30 minutes.

A solution treatment may be used to remove the polymer and silica substances. Some of the widely used solutions including water, alcohol, acetone, chloroform, methylene chloride, ethyl acetate, benzene, toluene, xylene, tetrahydrofuran, hexane, diethyl ether, hydrofluoric acid or mixtures thereof may be employed.

The de-cored (core-removed) hollow particles may have an average external diameter of 50 nm-100 μm. Where the average external diameter thereof is less than 50 nm, the scattering effect of light may be reduced, and where it is greater than 100 μm, processability of the electrolyte may be reduced. Such hollow particles have a hollow shell structure having an empty central portion, and are composed of the metal oxide particulates.

The composite electrolyte according an exemplary embodiment may be obtained by adding the thusly obtained hollow particles into the electrolyte and mixing them together. Here, the weight percent of the hollow particles to the electrolyte may be in the range of 1:1000-2:1. Where added in an amount less than 1:1000, the effect obtained by adding the hollow particles may become reduced, and where added in an amount more than 2:1, the processability of the electrolyte may be reduced.

FIG. 3 shows a diagram schematically illustrating the promotion of ion diffusion and the increase of the light scattering effect where the above-fabricated hollow particles are used. The surfaces of the hollow particles interact with positive ions and negative ions within the electrolyte, thereby contributing to the dissociation of the ions. Further, the surfaces of the hollow particles provide a pathway such that the ions may be efficiently transmitted between the photoelectrode and the counter electrode, thereby enhancing the diffusion of the ions. Since the hollow particles having a size of several tens-several thousands nm have a light scattering effect, the utilization of sunlight may be maximized, thereby increasing the optical absorption of the dye.

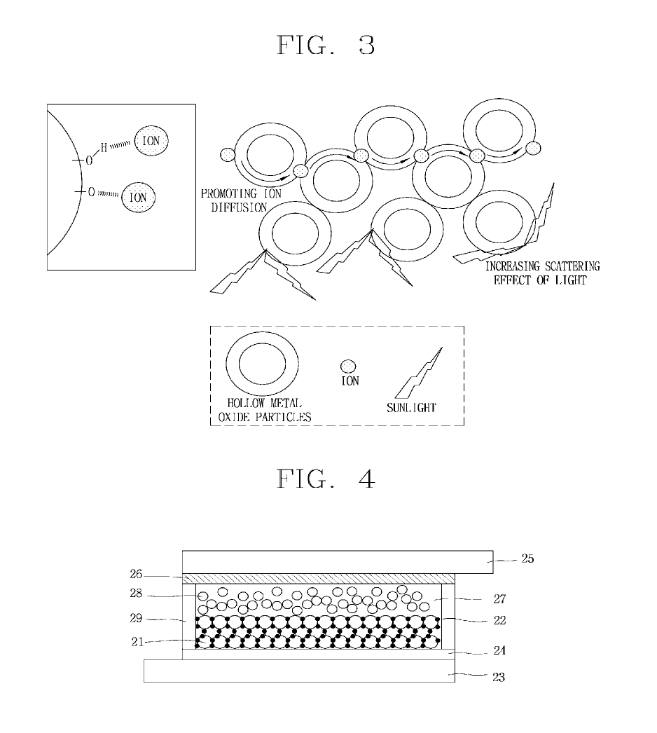

FIG. 4 shows an exemplary dye-sensitized solar cell implementing an electrolyte with the thusly prepared hollow particles. Referring to FIG. 4, the dye-sensitized solar cell according an exemplary embodiment includes a photoelectrode substrate 23, a counter electrode substrate 25 facing the photoelectrode substrate 23, a light absorbing layer 21 disposed on an inner surface of the photoelectrode substrate 23 and having a dye 22 adsorbed thereto, and an electrolyte 27 filled between the light absorbing layer 21 and the counter electrode substrate 25 and mixed with hollow particles 28. Reference numeral 24 denotes a blocking layer. The blocking layer may be selectively inserted so as to provide adhesion between the light absorbing layer 21 and the photoelectrode substrate 23, to perform electron transport, and to prevent the leakage of electrons transmitted from the photoelectrode substrate 23. In addition, reference numeral 26 denotes a platinum layer, and reference numeral 29 denotes a sealing material.

For the photoelectrode substrate 23 and the counter electrode substrate 25, a transparent conducting glass substrate having a conducting thin film formed thereon, or a flexible transparent conducting polymer substrate having a conducting thin film formed thereon may be used. As the conducting thin film, ITO (indium tin oxide), FTO (F-doped SnO₂), or ATO (Antimony Tin Oxide) or FTO-coated ITO may be used.

In addition, a well-known semiconductor oxide layer may be used for the light absorbing layer 21. And, the dye 22 is adsorbed onto the light absorbing layer. Here, the dye may be a ruthenium (Ru)-based dye or organic dye.

Further exemplary embodiments consistent with the above teachings are provided below.

### Example 1

### Preparation of Hollow Particles of Metal Oxide

5 g of polystyrene nano particles in a spherical shape having a size of 500 nm were mixed with 3.65 g of Al₂O₃ nano particles having a size of 20-30 nm, and placed in a mechanofusion apparatus (Hosakawa Micron), and then processed at 2500 rpm for 30 minutes, thereby preparing a metal oxide adsorbent. In order to remove the cores (polystyrene) of the prepared metal oxide adsorbent, the resultant material was heated from room temperature up to 500° C. at 0.2° C. per minute in an air atmosphere, heat-treated at 500° C. for 120 minutes, and then was allowed to cool naturally.

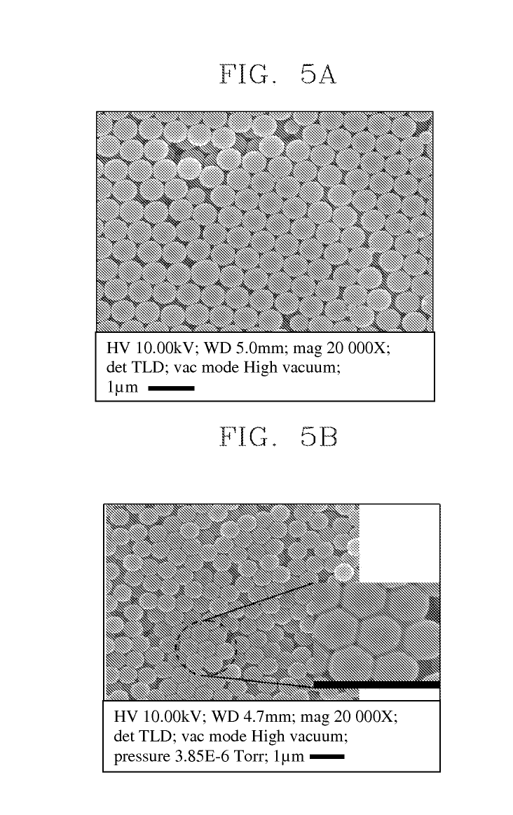

FIG. 5A shows the polystyrene cores before performing the processing, and FIG. 5B shows the cores have been removed after adsorbing Al₂O₃ nano particles through mechanofusion. As shown in FIG. 5B, it is observed that hollow particles of the metal oxide were well formed.

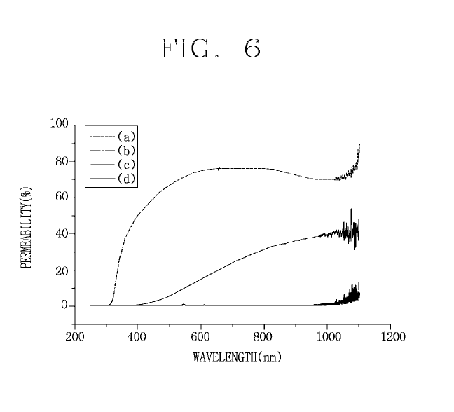

FIG. 6 shows a graph of UV permeability measuring the light scattering effect of the prepared hollow particles of the metal oxide. The line (a) shows the permeability of the transparent conducting substrate, the line (b) shows the permeability where metal oxides in a nano-particle form are coated on the transparent conducting substrate, the line (c) shows the permeability where particles having a size of approximately 400 nm and additionally introduced on the light absorbing layer so as to scatter light are coated on the transparent conducting substrate, and the line (d) shows the permeability where hollow particles of metal oxide prepared according an exemplary embodiment are coated on the transparent conducting substrate. Comparing lines (c) and (d), it is observed that in line (d) light is scattered efficiently enough that the permeability almost reaches 0, similarly to line (c).

### Example 2

### Preparation of a Composite Electrolyte

An electrolyte was prepared based on a liquid electrolyte having iodine-based oxidation-reduction pairs and based on ionic liquid (e.g., an electrolyte prepared by mixing 1-butyl-3-methyl-imidazolium iodide with 10 mol % of iodine (I₂)). The above-prepared exemplary hollow particles of metal oxide were added so as to make the weight percent of the hollow particles of metal oxide to the electrolyte itself be 1:1.

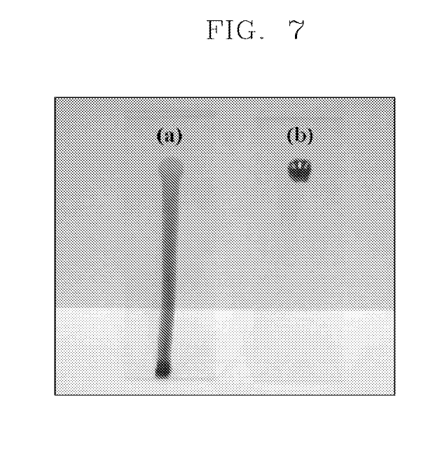

FIG. 7 shows check of the mechanical properties of the electrolyte having the hollow particles of metal oxide according to an exemplary embodiment (i.e., the composite electrolyte). For the case (a) of an electrolyte into which the hollow particles of metal oxide were not added, the liquidity becomes high due to a low viscosity, thereby increasing the possibility of causing a leakage and reducing the mechanical stability of a dye-sensitized solar cell. In comparison, for the case (b) of an electrolyte into which the hollow particles of metal oxide were added, a high viscosity may reduce the possibility of a leakage even where the solar cell is broken, and also the mechanical properties of the solar cell itself are enhanced.

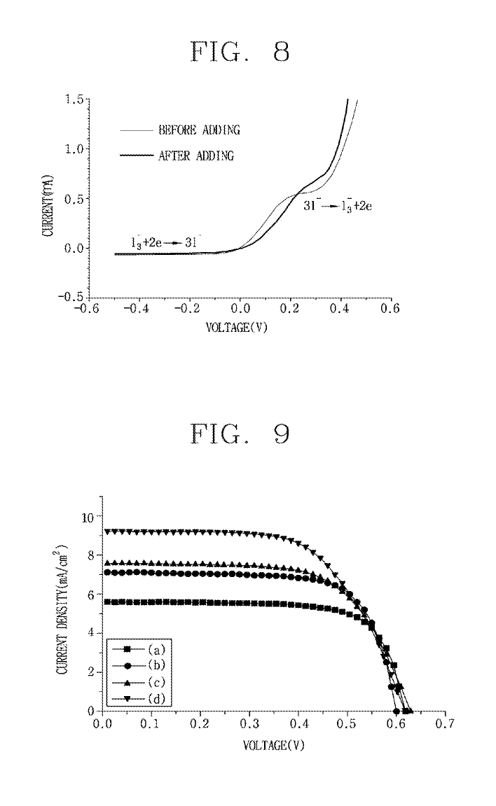

FIG. 8 shows a steady-state current graph measuring the degree of promoting ion diffusion of the electrolyte into which the hollow particles of metal oxide are added according to an exemplary embodiment (i.e., the composite electrolyte). When comparing the times before and after the hollow particles of metal oxide were added, for I⁻, it is observed that the ion diffusion coefficient increased by 60.4%. Such an increase in the ion diffusion greatly increases the dye-sensitized solar cell performance.

### Example 3

### Preparation of a Dye-Sensitized Solar Cell

The electrolyte having the hollow particles of the metal oxide according to an exemplary embodiment was applied to a dye-sensitized solar cell fabricated through the following procedures.

A 5% Ti(IV) bis(ethyl acetoacetato)-diisopropoxide)/1-butanol solution was spin-coated (1^{st}: 500 rpm, 5 sec; 2^{nd}: 1000 rpm, 5 sec; 3^{rd}: 2000 rpm, 40 sec) on a transparent conducting substrate (fluorine-doped tin oxide glass (SnO₂:F, FTO), sheet resistance 8 Ω/cm², Pilkington). Then, the resultant structure was heated from room temperature up to 500° C. at 4° C. per minute in an air atmosphere, and was heat-treated at 500° C. for 15 minutes, and then naturally cooled, thus to form a blocking layer.

A TiO₂ paste (STI, 18NR-T) was coated on the thusly prepared blocking layer by using a doctor blade. The resultant structure was heated from room temperature up to 150° C. at 4° C. per minute in an air atmosphere, and isothermally maintained at 150° C. for 30 minutes. Then, the resultant structure was heated again up to 500° C. at 4° C. per minute, was heat-treated at 500° C. for 15 minutes, and then was naturally cooled, thereby forming a TiO₂ electrode having a thickness of approximately 12 μm. The TiO₂ electrode was soaked in a dye solution for 24 hours, thereby adsorbing the dye molecules onto the electrode. In this example, N719 (Solaronix) of 0.5 mM concentration/ethyl alcohol solution was used.

In order to form a platinum layer of the counter electrode, a 10 mM concentration of H₂PtCl₆.xH₂O, (Aldrich)/isopropyl alcohol solution was spin-coated (1^{st}: 500 rpm, 5 sec; 2^{nd}: 1000 rpm, 5 sec; 3^{rd}: 2000 rpm, 40 sec) on a transparent conducting substrate. Then, the resultant structure was heated from room temperature up to 400° C. at 4° C. per minute in an air atmosphere, then was heat-treated at 400° C. for 15 minutes, and then naturally cooled.

After the prepared composite electrolyte was injected between the photoelectrode and the counter electrode, the photoelectrode and the counter electrode were coupled. Here, a thermoplastic polymer having a thickness of 25 μm was used as a sealing material for preventing the leakage of the electrolyte solution.

[Comparison 1]

A dye-sensitized solar cell, in which an electrolyte without metal oxide nano particles was applied to a metal oxide semiconductor electrode (a light scattering layer was not introduced onto this electrode), was fabricated the same as in the above-described Example 3.

[Comparison 2]

A dye-sensitized solar cell, in which an electrolyte with Al₂O₃ having a nano powder shape (instead of a hollow shape) was applied to a metal oxide semiconductor electrode (a light scattering layer was not introduced onto this electrode), was fabricated the same as in Example 3.

[Comparison 3]

A dye-sensitized solar cell, in which an electrolyte without metal oxide nano particles was applied to a metal oxide semiconductor electrode (a layer for scattering light and composed of nano particles having a size of approximately 400 nm was introduced on this electrode), was fabricated the same as in Example 3.

FIG. 9 shows current-voltage graphs obtained where each of the dye-sensitized solar cells prepared according to (a) Comparison 1, (b) Comparison 2, (c) Comparison 3, (d) Example 3 were under a condition of AM 1.5, 100 mW/cm². Table 1 shows the detailed values.

TABLE 1

| | open- | short circuit | | energy |
|---|---|---|---|---|
| | circuit | current | fill | conversion |
| | voltage (V) | (mA/cm²) | factor | efficiency (%) |
| (a) Comparison 1 | 0.62 | 5.61 | 0.72 | 2.50 |
| (b) Comparison 2 | 0.60 | 7.11 | 0.71 | 3.04 |
| (c) Comparison 3 | 0.63 | 7.62 | 0.64 | 3.07 |
| (d) Example 3 | 0.61 | 9.22 | 0.62 | 3.50 |

Referring to FIG. 9 and Table 1, a solar cell according to an exemplary embodiment showed a remarkably enhanced value in short-circuit current, compared to the Comparisons 1-3. As a result, the energy conversion efficiency showed a 40% increase compared to where there was no ion diffusion effect and light scattering effect (Comparison 1), and a 14% increase compared to where there was either an ion diffusion effect (Comparison 2) or a light scattering effect (Comparison 3).

According to certain embodiments described above, the energy conversion efficiency of a dye-sensitized solar cell may be highly enhanced by promoting ion diffusion within the electrolyte and by increasing the light scattering effect. Furthermore, the durability of a solar cell may be enhanced by improving the mechanical strength of the solar cell through gelation of the electrolyte.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A composite electrolyte, characterized in that an electrolyte is mixed with hollow particles composed of metal oxide particulates.

2. The composite electrolyte of claim 1, wherein a weight percent of the hollow particles to the electrolyte is 1:1000-2:1.

3. The composite electrolyte of claim 1, wherein the hollow particles have an average external diameter of 50 nm-100 μm, and the metal oxide particulates have an average diameter of 1 nm-10 μm.

4. The composite electrolyte of claim 1, wherein the hollow particles have an average shell thickness of 10 nm-10 μm.

5. The composite electrolyte of claim 1, wherein the metal oxide particulates are one or a composite of two or more selected from a group consisting of Al oxide, Si oxide, Ti oxide, In oxide, Zn oxide, Sn oxide, W oxide, Pb oxide, Mg oxide, Ga oxide, Zr oxide, Sr oxide, Mo oxide, V oxide, Yr oxide, Sc oxide, Sm oxide, FeTi oxide, MnTi oxide, BaTi oxide and SrTi oxide.

6. A dye-sensitized solar cell, comprising:
a photoelectrode substrate;
a counter electrode substrate facing the photoelectrode substrate;
a light absorbing layer formed on an inner surface of the photoelectrode substrate and having a dye adsorbed thereto; and
a composite electrolyte, characterized in that an electrolyte is mixed with hollow particles composed of metal oxide particulates, filled between the light absorbing layer and the counter electrode substrate.

7. A preparation method for a composite electrolyte, the method comprising:
forming metal oxide adsorbents by adsorbing metal oxide particulates onto cores, and then obtaining hollow particles by removing the cores from the metal oxide adsorbents; and
obtaining the composite electrolyte by mixing the hollow particles with an electrolyte.

8. The method of claim 7, wherein the cores are a polymer or its derivatives, or silica or its derivatives.

9. The method of claim 8, wherein the polymer is one or a composite of two or more selected from a group consisting of polystyrene, styrene/divinylbenzene copolymer, polymethylmethacrylate, polyvinyltoluene, and styrene/butadiene copolymer.

10. The method of claim 7, wherein the cores have an average diameter of 50 nm-100 μm.

11. The method of claim 7, wherein the metal oxide particulates are one or a composite of two or more selected from a group consisting of Al oxide, Si oxide, Ti oxide, In oxide, Zn oxide, Sn oxide, W oxide, Pb oxide, Mg oxide, Ga oxide, Zr oxide, Sr oxide, Mo oxide, V oxide, Yr oxide, Sc oxide, Sm oxide, FeTi oxide, MnTi oxide, BaTi oxide and SrTi oxide.

12. The method of claim 7, wherein a diameter ratio of the cores to the metal oxide particulates is in the range of 10:1-100000:1.

13. The method of claim 7, wherein the metal oxide adsorbents are formed by a dry method or a wet method,
wherein the dry method is one of a mechanical adsorption using a mixing device, sputtering, e-beam evaporation, thermal evaporation, laser molecular beam epitaxy, pulsed laser deposition, MOCVD (Metal-Organic Chemical Vapor Deposition), HVPE (Hydiride Vapor Phase Epitaxy), electro deposition, atomic layer deposition, or MOMBE (Metal-Organic Molecular Beam Epitaxy), and
wherein the wet method is one of emulsion polymerization, electrophoresis, dip coating, or a chemical vapor deposition using a surface functional group.

14. The method of claim 7, wherein removal of the cores from the metal oxide adsorbents is performed by a heat treatment or a solution treatment,
wherein the heat treatment comprises heating the metal oxide adsorbents at a rate of less than 10° C. per minute, and performing a heat treatment at a temperature in the range of 300-1000° C. for 5 min.-48 hours, and
wherein the solution treatment uses, as a solvent, one or a composite of two or more selected from a group consisting of water, alcohol, acetone, chloroform, methylene chloride, ethyl acetate, benzene, toluene, xylene, tetrahydrofuran, hexane, diethyl ether and hydrofluoric acid.
